(19) United States
(12) Patent Application Publication
(10) Pub. No.: US 2022/0149062 A1
(43) Pub. Date: May 12, 2022

(54) THREE-DIMENSIONAL NAND MEMORY DEVICE WITH NOVEL DUMMY CHANNEL STRUCTURES

(71) Applicant: Yangtze Memory Technologies Co., Ltd., Wuhan (CN)

(72) Inventors: QiangWei ZHANG, Wuhan (CN); Jingjing GENG, Wuhan (CN); Zongke XU, Wuhan (CN)

(73) Assignee: Yangtze Memory Technologies Co., Ltd., Wuhan (CN)

(21) Appl. No.: 17/159,207

(22) Filed: Jan. 27, 2021

Related U.S. Application Data
(63) Continuation of application No. PCT/CN2020/126983, filed on Nov. 6, 2020.

(51) Int. Cl. H01L 27/11556; H01L 27/11582; H01L 27/11565; H01L 27/1157; H01L 27/11524; H01L 27/11519; G11C 8/14

(52) U.S. Cl. CPC H01L 27/11556; H01L 27/11582; H01L 27/11565; G11C 8/14; H01L 27/11524; H01L 27/11519; H01L 27/1157

(57) ABSTRACT

A semiconductor device is provided. The semiconductor device includes a stack of word line layers and insulating layers that are alternatingly arranged in a vertical direction perpendicular to a substrate of the semiconductor device. The stack includes a first array region and an adjacent first staircase region. The semiconductor device includes a dummy channel structure that extends in the vertical direction through the word line layers and the insulating layers in the first staircase region of the stack. At least one of the word line layers is located further away from a central axis of the dummy channel structure than the insulating layers adjacent to the at least one of the word line layers.

### RELATED APPLICATION

This application is a bypass continuation of International Application No. PCT/CN2020/126983, filed on Nov. 6, 2020. The entire disclosure of the prior application is hereby incorporated by reference in its entirety.

### BACKGROUND

Flash memory devices have recently been through a rapid development. The flash memory devices are able to retain stored data for a long period of time without applying a voltage. Further, the reading rate of the flash memory devices is relatively high, and it is easy to erase stored data and rewrite data into the flash memory devices. Thus, the flash memory devices have been widely used in micro-computers, automatic control systems, and the like. To increase the bit density and reduce the bit cost of the flash memory devices, three-dimensional (3D)-NAND (Not AND) memory devices have been developed.

The 3D-NAND memory devices can include a stack of alternating word line layers and insulating layers positioned over a substrate. The stack can include array regions and staircase regions. Channel structures can be formed in the array regions, and dummy channel structures can be formed in staircase regions. The dummy channel structures are configured to support the staircase regions when the word line (or gate line) layers are formed based on a gate-last fabrication technology, where sacrificial layers can be formed firstly, and then be replaced with the word line layers. In recent years, as the cell layers of the 3D-NAND exceeds 100 layers, it is increasingly challenging to form word line layers (or gate line layers) based on the gate-last fabrication technology because collapses can take place in the staircase regions during the formation of the word line layers.

### SUMMARY

In the present disclosure, embodiments directed to a 3D-NAND memory device that includes dummy channel structures in a thread configuration and a method of manufacturing the same are provided.

In the present disclosure, a semiconductor device is provided. The semiconductor device can include a stack of word line layers and insulating layers that are alternatingly arranged in a vertical direction perpendicular to a substrate of the semiconductor device. The stack can include a first array region and an adjacent first staircase region. The semiconductor device can include a dummy channel structure that extends in the vertical direction through the word line layers and the insulating layers in the first staircase region of the stack. At least one of the word line layers can be located further away from a central axis of the dummy channel structure than the insulating layers adjacent to the at least one of word line layers.

In some embodiments, each of the word line layers can be located further away from the central axis of the dummy channel structure than the insulating layers adjacent to the respective word line layer.

The semiconductor device can further include an isolation layer that is formed over the substrate, where the first staircase region can be positioned in the isolation layer, and the dummy channel structure can extend into the substrate and further extend through the isolation layer in the vertical direction.

Further, the dummy channel structure can include a dummy layer that is arranged along the word line layers and the insulating layers, and further extends into the substrate.

In some embodiments, the semiconductor device can include a second array region, where the first staircase region is arranged between the first array region and the second array region.

In other embodiments, the semiconductor device can include a second staircase region, where the first array region is arranged between the first staircase region and the second staircase region.

In some embodiments, the dummy channel structure can have a circular cross-section that is perpendicular to the central axis. In other embodiments, the dummy channel structure can have a non-circular cross-section that is perpendicular to the central axis.

In the dummy channel structure, the dummy layer can include at least one of SiO, SiN, SiCN, SiCON, SiON, or polysilicon.

The semiconductor device can also include a plurality of channel structures, one or more slit structures, and a plurality of word line contacts. The channel structures can be formed in the first array region, and extend through the word line layers and the insulating layers, and further extend into the substrate. The one or more slit structures can extend in a horizontal direction parallel to the substrate, and further extend into the substrate. In some embodiments, the one or more slit structures can further extend through the first array region and the first staircase region so as to being arranged among the channel structures. The word line contacts can extend from the word line layers of the first staircase region in the vertical direction.

In some embodiments, the semiconductor device can include another dummy channel structure that extends in the vertical direction through the word line layers and the insulating layers in the first array region of the stack.

According to another aspect of the disclosure, a method for manufacturing a semiconductor device is provided. In the method, an initial stack can be formed. The initial stack can include sacrificial layers and insulating layers that are alternatingly arranged in a vertical direction perpendicular to a substrate. The initial stack can include a first array region and an adjacent first staircase region. A dummy channel hole can be subsequently formed. The dummy channel hole can extend in the vertical direction through the sacrificial layers and the insulating layers in the first staircase region, and further extend into the substrate. An etching process can be performed to recess portions of the sacrificial layers from a central axis of the dummy channel hole such that at least one of the sacrificial layers is located further away from the central axis of the dummy channel hole than the insulating layers adjacent to the at least one of the sacrificial layers.

In order to form the dummy channel hole, an isolation layer can be formed over the substrate such that the first staircase region is arranged in the isolation layer. Subsequently, the dummy channel hole can be formed to extend through the isolation layer, and the sacrificial layers and the insulating layers in the first staircase region.

Further, a dummy layer can be deposited in the dummy channel hole to form a dummy channel structure, where the dummy layer is arranged along the sacrificial layers and the insulating layers, and further extends into the substrate.

In the method, a channel structure can be formed in the first array region of the initial stack, where the channel structure can extend through the sacrificial layers and the insulating layers, and further extend into the substrate.

In addition, a slit structure can be formed to extend in a horizontal direction parallel to the substrate, and further extend into the substrate. In some embodiments, the slit structure can further extend through the first array region and the first staircase region. Further, the sacrificial layers can be replaced with word line layers in the initial stack so as to form a stack of alternating word line layers and insulating layers, where the word line layers can be formed of a conductive material. Moreover, word line contacts can be formed to extend from the word line layers of the first staircase region in the vertical direction.

In some embodiments, the initial stack can include a second array region, where the first staircase region can be arranged between the first array region and the second array region.

In some embodiments, the initial stack can include a second staircase region, where the first array region can be arranged between the first staircase region and the second staircase region.

In some embodiments, the dummy channel hole can have a cross-section that is perpendicular to the central axis. The cross-section can have a circular shape or a non-circular shape.

According to another aspect of the disclosure, a 3D-NAND memory device is provided. The 3D-NAND memory device can include a stack of word line layers and insulating layers that are alternatingly arranged in a vertical direction perpendicular to a substrate of the 3D-NAND memory device. The stack can include a first array region and an adjacent first staircase region. The 3D-NAND memory device can also include a dummy channel structure that extends in the vertical direction through the word line layers and the insulating layers in the first staircase region of the stack, where at least one of the word line layers is located further away from a central axis of the dummy channel structure than the insulating layers adjacent to the at least one of the word line layers. The 3D-NAND memory device can include a channel structure that is formed in the first array region. The channel structure can extend through the word line layers and the insulating layers, and further extends into the substrate. The 3D-NAND memory device can include a slit structure that extends in the substrate. The slit structure can further extend in a horizontal direction parallel to the substrate so as to extend through the first array region and the first staircase region. The 3D-NAND memory device can further include word line contacts that extend from respective word line layers of the first staircase region in the vertical direction.

In some embodiments, each of the word line layers can be located further away from the central axis of the dummy channel structure than the insulating layers adjacent to the respective word line layer.

In the semiconductor device, the dummy channel structure can include a dummy layer that is arranged along the word line layers and the insulating layers, and further extends into the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is cross-sectional view of an exemplary 3D-NAND memory device, in accordance with exemplary embodiments of the disclosure.

FIG. 2 is a cross-sectional view of a dummy channel structure, in accordance with exemplary embodiments of the disclosure.

FIGS. 3-6 are cross-sectional views of various intermediate steps of manufacturing a dummy channel structure, in accordance with exemplary embodiments of the disclosure.

FIG. 7 is a flowchart of a process for manufacturing a 3D-NAND memory device, in accordance with exemplary embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features may be in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A 3D-NAND memory device can include staircase regions and array regions that are formed in a stack of word line layers and insulating layers. The word line layers and the insulating layers can be disposed alternatingly over a substrate. The word line layers can include one or more bottom select gate (BSG) layers, gate layers (or word line layers), and one or more top select gate (TSG) layers that are arranged sequentially over the substrate. The array regions can include a plurality of channel structures. Each of the channel structures can be coupled to the word line layers to form a respective vertical NAND memory cell string. The vertical NAND memory cell string can include one or more bottom select transistors (BSTs), a plurality of memory cells (MCs), and one or more top select transistors (TSTs) that are disposed sequentially and in series over the substrate along a height direction (or Z direction) of the substrate. The one or more BSTs can be formed of the channel structure and the one or more BSG layers, the MCs can be formed of the channel structure and the word line layers, and the one or more TSTs can be formed of the channel structure and the one or more TSG layers.

In the 3D-NAND device, the staircase regions can include a plurality of dummy channel structures that are configured to support/sustain the staircase regions during formation of the word line layers based on a gate-last fabrication technology. In the gate-last fabrication technology, an initial stack of alternating sacrificial layers and insulating layers can be formed over the substrate. The channel structures can be formed subsequently in the initial stack and the sacrificial layers can then be removed and replaced with the word line layers. In a related example, collapses of the insulating layers can take place when the sacrificial layers are removed because spaces are formed between the insulating layers. The collapses can be worse when spacing between the dummy channel structures is increased.

In the disclosure, dummy channel structures, for example with a thread configuration, are provided. The dummy channel structure can include a first sidewall that is formed along the insulating layers and around a central axis, and a second sidewall that is formed along the word line layers and around the central axis, where the second sidewall is located further away from the central axis than the first sidewall. Based on the thread configuration, an effective critical dimension (CD) of the dummy channel structures can be increased. Thus, the spacing between the dummy channel structures can be reduced, and collapses in the staircase regions can be prevented.

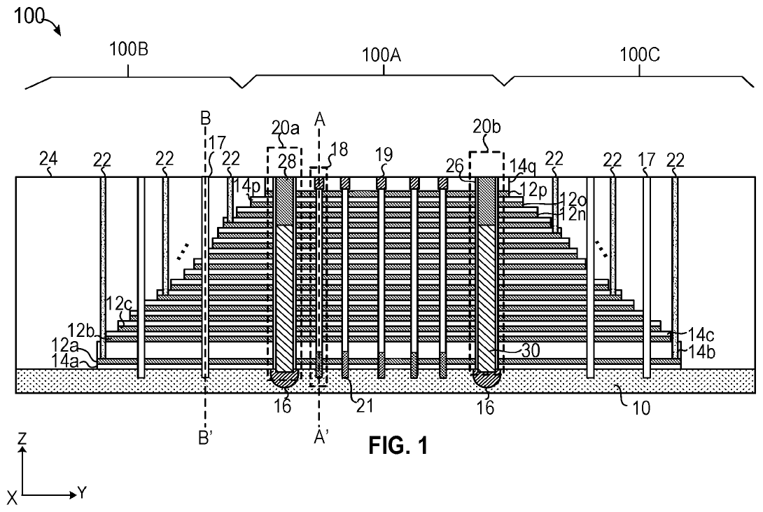

FIG. 1 is a cross-sectional view of an exemplary 3D-NAND memory device 100 (also referred to as device 100). As shown in FIG. 1, the 3D-NAND memory device 100 can have a substrate 10. A plurality of word line layers 12a-12p and a plurality of insulating layers 14a-14q are stacked alternatingly over the substrate 10. In the exemplary embodiment of FIG. 1, 16 word line layers and 17 insulating layers are included. It should be noted that FIG. 1 is merely an example, and any number of word line layers and insulating layers can be included based on the device structure.

In some embodiments, a lowermost word line layer 12a can function as a bottom select gate (BSG) layer that is connected to a gate of a BST. In some embodiments, one or more of the word line layers over the BSG layer 12a, such as word line layer 12b-12c, can be dummy word line layers (or dummy BSG layers) that are connected to gates of dummy memory cells (dummy MCs). The BST and the dummy MCs together can control data transmission between array common source (ACS) regions 16 and the memory cells.

In some embodiments, an uppermost word line layer 12p can function as a top select gate (TSG) layer that is connected to a gate of a TST. In some embodiments, one or more of the word line layers under the TSG layer 12p, such as word line layers 12n-12o, can be dummy word line layers (or dummy TSG layers) that are connected to gates of dummy memory cells (dummy MCs). The TST and the dummy MCs together control data transmission between bit lines (not shown) and the memory cells.

The insulating layers 14a-14q can be positioned on the substrate 10 and arranged with the word line layers 12a-12p alternatingly. The word line layers 12a-12p are spaced part from one another by the insulating layers 14a-14q. In addition, the word line layers 12a-12p are separated from the substrate 10 by a lowermost insulating layer 14a of the insulating layers 14a-14q.

In some embodiments, the word line layers 12a-12p illustrated in FIG. 1 can be formed first using sacrificial word line layers (or sacrificial layers), such as SiN. The sacrificial word line layers can be removed and replaced with a high K layer, glue layers, and one or more metal layers. The high K layer can be made of aluminum oxide (Al₂O₃) Hafnium oxide (HfO₂), Tantalum oxide (Ta₂O₅), and/or another material of high K (Dielectric Constant). The metal layer can be made of tungsten (W), or Cobalt (Co), for example. The word lines can have a thickness in a range from 10 nm to 100 nm, according to requirements of product specification, device operation, manufacturing capabilities, and so on. In an embodiment of FIG. 1, the insulating layers can be made of SiO₂ with a thickness from 5 nm to 50 nm.

In some embodiments, the 3D-NAND memory device 100 can have an array region 100A and two staircase regions 100B-100C. The staircase regions 100B-100C can be positioned at two sides of the array region 100A. The word line layers and the insulating layers can extend into the staircase region 100B-100C with a stair-cased profile or step-cased profile.

The 3D-NAND memory device 100 can include a plurality of channel structures 18 in the array region 100A. The channel structures 18 are formed over the substrate 10 along a Z-direction (also referred to as vertical direction or height direction) of the substrate. As shown in FIG. 1, five channel structures 18 are included. However, FIG. 1 is merely an example, and any number of channel structures 18 can be included in the 3D-NAND memory device 100. The channel structures 18 can extend through the word line layers 12a-12p and the insulating layers 14a-14q, and further extend into the substrate 10 to form an array of vertical memory cell strings. Each of the vertical memory cell strings can include a corresponding channel structure that is coupled to the word line layers 12a-12p to form one or more bottom select transistors (BSTs), a plurality of memory cells (MCs), and one or more top select transistors (TSTs). The one or more BSTs, MCs, and one or more TSTs are disposed sequentially and in series over the substrate. In addition, each of the channel structures 18 can further include a channel layer (not shown), a tunneling layer (not shown), a charge trapping layer (not shown), and a barrier layer (not shown) that are concentrically arranged around a central axis A-A′ in the vertical direction.

Moreover, each of the channel structures 18 can further include a top channel contact 19 and a bottom channel contact 21. The bottom channel contact 21 can extend into the substrate 10. The channel layer, the tunneling layer, the charge trapping layer, and the barrier layer can be positioned over the bottom channel contact 21. The barrier layer can be formed in the vertical direction and in direct contact with the word line layers 12a-12p and the insulating layers 14a-14q. The charge trapping layer can be formed along an inner surface of the barrier layer. The tunneling layer can be formed along an inner surface of the charge trapping layer, and the channel layer can be formed along an inner surface of the tunneling layer. The top channel contact 19 can be formed along an inner surface of the channel layer and further arranged over a dielectric layer (not shown) that is formed along the inner surface of the channel layer. The dielectric layer can further be disposed over the bottom channel contact 21.

In an embodiment of FIG. 1, the barrier layer is made of SiO₂. In another embodiment, the barrier layer can include multiple layers, such as SiO₂ and Al₂O₃. In an embodiment of FIG. 1, the charge trapping layer is made of SiN. In another embodiment, the charge trapping layer can include a multi-layer configuration, such as a SiN/SiON/SiN multi-layer configuration. In some embodiments, the tunneling layer can include a multi-layer configuration, such as a SiO/SiON/SiO multi-layer configuration. In an embodiment of FIG. 1, the channel layer is made of polysilicon via a furnace low pressure chemical vapor deposition (CVD) process. The channel insulating layer can be made of SiO₂, and the top and bottom channel contacts 19 and 21 can be made of polysilicon.

The 3D-NAND memory device 100 can have a plurality of slit structures (or gate line slit structures). For example, two slit structures 20a-20b are included in FIG. 1. In some embodiments, a gate-last fabrication technology is used to form the 3D-NAND memory device 100, thus the slit structures are formed to assist in the removal of the sacrificial word line layers, and the formation of the real gates. In some embodiments, the slit structures can be made of conductive materials and positioned on array common source (ACS) regions 16 to serve as contacts. The ACS regions are formed in the substrate 10 to serve as common sources. In some embodiments, the slit structures can be made of dielectric materials to serve as separation structures. In an exemplary embodiment of FIG. 1, the slit structures 20a-20b are positioned at two opposing boundaries of the array region 100A and connected to the ACS regions 16.

In some embodiments, the slit structures 20a-20b can extend through the word line layers 12a-12p and the insulating layers 14a-14q, and further extend along a first direction (also referred to as a length direction, or a X direction) of the substrate 10. In some embodiments, the slit structures 20a-20b can have a dielectric spacer 26, a conductive layer 30, and a contact 28. The dielectric spacer 26 can be formed along sidewalls of the slit structures and in direct contact with the word line layers and the insulating layers. The conductive layer 30 can be formed along the dielectric spacer 26 and over the ACS regions 16. The contact 28 can be formed along the dielectric spacer 26 and over the conductive layer 30. In an embodiment of FIG. 1, the dielectric spacer 26 is made of SiO₂, the conductive layer 30 is made of polysilicon, and the contact 28 is made of tungsten.

The device 100 can further include a plurality of dummy channel structures 17 arranged in the staircase regions 100B and 100C. The dummy channel structures can extend in the vertical direction through the word line layers 12a-12p and the insulating layers 14a-14q in the staircase regions 100B and 100C. The dummy channel structures 17 can be configured to support the staircase regions when the word line (or gate line) layers 12a-12p are formed based on a gate-last fabrication technology. In some embodiments, the dummy channel structures 17 and the channel structures 18 are formed of the same materials, and have similar configurations. Thus, each of the dummy channel structures 17 can include a channel layer, a tunneling layer, a charge trapping layer, and a barrier layer that are concentrically arranged around a vertical axis B-B′. In some embodiments, the channel structures 17 and the channel structures 18 are made of different materials, and have different configurations. For example, the dummy channel structures 17 can be made of a dielectric material.

The 3D-NAND memory device 100 can have a plurality of word line contact structures (or word line contacts) 22. The word line contact structures 22 are formed in a dielectric layer (or isolation layer) 24 and positioned on the word line layers 12a-12p to connect to the word line layers 12a-12p. For simplicity and clarity, only three word line contact structures 22 are illustrated in each of the staircase regions 100B and 100C. The word line contact structures 22 can further be coupled to gate voltages. The gate voltages can be applied to gates of the BSTs, the MCs, and the TSTs through the word line layers 12 to operate the BSTs, the MCs, and the TSTs correspondingly.

It should be noted that FIG. 1 is merely an example. In an exemplary embodiment of FIG. 1, the device 100 can include a first array region (e.g., the array region 100A), a first staircase region (e.g., the staircase region 100B), and a second staircase region (e.g., the staircase region 100C), where the first array region is arranged between the first staircase region and the second staircase region. In another exemplary embodiment, the device 100 can include a first array region, a second array region, and a first staircase region. The first staircase region can be arranged between the first array region and the second array region.

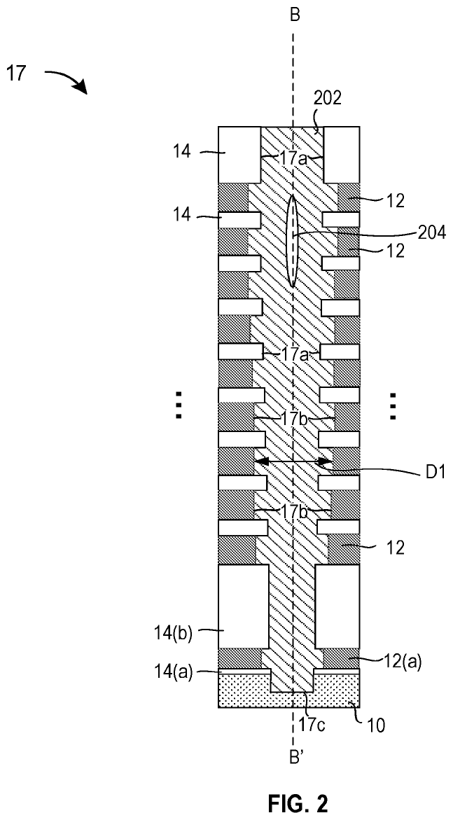

FIG. 2 is a cross-sectional view of a dummy channel structure 17. As shown in FIG. 2, the dummy channel structure 17 can have a cylindrical profile and extend into the substrate 10. The dummy channel structure 17 can extend through the word line layers 12 and the insulating layers 14 in the vertical direction (or Z-direction). The dummy channel structure 17 can have a cross-section that is perpendicular to the central axis B-B′. In some embodiments, the cross-section can have a circular shape. In other embodiments, the cross-section can have a non-circular shape, such as a capsule shape, a rectangular shape, and an arc shape.

Still referring to FIG. 2, the dummy channel structure 17 can have a first sidewall 17a along the insulating layers 14, a second sidewall 17b along the word line layers 12, and a bottom 17c positioned in the substrate 10. The word lines layers 12 are located further away from the central axis B-B′ than the insulating layers 14. In an embodiment, each of the word line layers 12 can be located further away from the central axis B-B′ than the insulating layers 14 adjacent to the respective word line layer. In another embodiment, a subset of the word line layers 12 can be located further away from the central axis B-B′ than the insulating layers 14 adjacent to the respective word line layer. The subset of the word line layers 12 can be the word line layers adjacent to a bottom portion of the dummy channel structure 17, the word line layers adjacent to a top portion of the dummy channel structure 17, or the word line layers adjacent to a middle portion of the dummy channel structure 17 according to process variations. For example, the word line layer 12a is located further from the central axis B-B′ than the adjacent insulating layers 14a and 14b. Thus, the second sidewall 17b can be recessed further from the central axis B-B′ than the first sidewall 17a. The dummy channel structure 17 can include a dummy layer 202 that is disposed along the first sidewalls 17a and the second sidewalls 17b. The dummy layer 202 can further be arranged over the bottom 17c of the dummy channel structure 17.

It should be noted that FIG. 2 just illustrates a portion of the dummy channel structure 17 that is disposed in the word line layers 12 and insulating layers 14. As shown in FIG. 1, the dummy channel structure 17 can further extend in the vertical direction and be disposed in the isolation layer 24. In addition, each of the dummy channel structures 17 can extend through a different number of word line layers and insulating layers in the staircase regions according to a position of the respective dummy channel structure.

Comparing to related examples, the dummy channel structure 17 can have a “thread configuration” or a staggered configuration, where a subset or all of the word line layers 12 are offset from the insulating layers 14. For example, the word line layers 12 can be located further away from the central axis B-B′ of the dummy channel structure 17 than the insulating layers 14. The thread configuration can increase an effective critical dimension (CD) of the dummy channel structure 17. The effective CD can be defined as D1 by the second sidewall 17b. Accordingly, spacing between two dummy channel structures 17 in the staircase regions (e.g., 100B or 100C) can be reduced and collapses in the staircase regions can be prevented.

In some embodiments, the dummy layer 202 can be made of SiO, SiN, SiCN, SiCON, or polysilicon. In some embodiments, one or more gaps (or voids) 204 can be formed in the dummy layer 202 during formation of the dummy layer 202. Any suitable deposition process can be applied to form the dummy layer 202, such as a chemical vapor deposition (CVD) process, a physical vapor deposition (PVD) process, a diffusion process, or an atomic layer deposition (ALD) process.

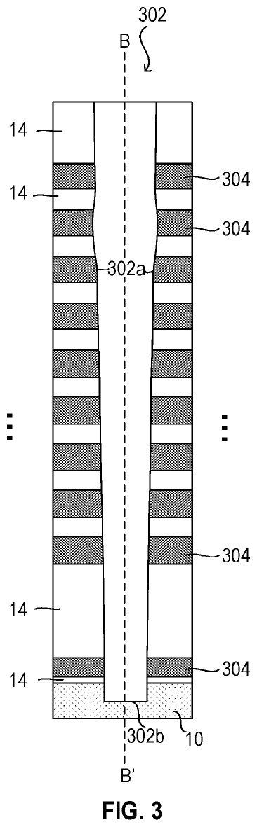

FIGS. 3-6 are cross-sectional views of various intermediate steps of manufacturing a dummy channel structure with a thread configuration. As shown in FIG. 3, an initial stack of alternating sacrificial layers 304 and insulating layers 14 can be formed over the substrate 10. In some embodiments, the initial stack can have a first array region (e.g., 100A), a first staircase region (e.g., 100B), and a second staircase region (e.g. 100C). The first array region is arranged between the first staircase region and the second staircase region. In some embodiments, the initial stack can have a first array region, a second array region, and a first staircase region. The first staircase region is arranged between the first array region and the second array region.

In an exemplary embodiment of FIG. 3, the sacrificial layers 304 can be made of a dielectric material, such as SiN, or any other suitable dielectric material. The insulating layer 14 can be made of SiO, for example. The sacrificial layers 304 and the insulating layer 14 can be formed through a CVD process, a PVD process, a diffusion process, an ALD process, or any other suitable deposition process, or a combination thereof.

Further, an isolation layer (e.g., 24) can be formed over the substrate 10 such that the initial stack can be covered by the isolation layer. A surface planarization process, such as a chemical-mechanical polishing (CMP) process, can be applied to remove excessive isolation layer over a top surface of the initial stack. When the CMP process is completed, a top surface of the isolation layer can be level with the top surface of the initial stack. A plurality of dummy channel holes can subsequently be formed in the initial stack. FIG. 3 illustrates an exemplary dummy channel hole 302. The dummy channel hole 302 can extend through the isolation layer (not shown), the sacrificial layers 304 and the insulating layers 14, and further extend into the substrate 10. The dummy channel hole 302 can have an initial sidewall 302a that is formed along the sacrificial layers 304 and the insulating layers 14, and a bottom 302b that is positioned in the substrate 10. In some embodiments, a cross-section of the dummy channel hole 302 that is perpendicular to the central axis B-B′ can have a circular shape. In other embodiments, the cross-section of the dummy channel hole 302 can have a non-circular shape, such as a capsule shape, a rectangular shape, and an arc shape.

In order to form the dummy channel hole 302, a patterning process can be operated that can include a photolithographic process and an etching process. The photolithographic process can form a patterned mask (not shown) with patterns over the isolation layer (e.g., 24), and the etching process can subsequently transfer the patterns into the isolation layer, and the initial stack. When the etching process is completed, the patterned mask can be removed by a dry strip process. The dummy channel hole 302 can be subsequently formed when the patterned mask is removed.

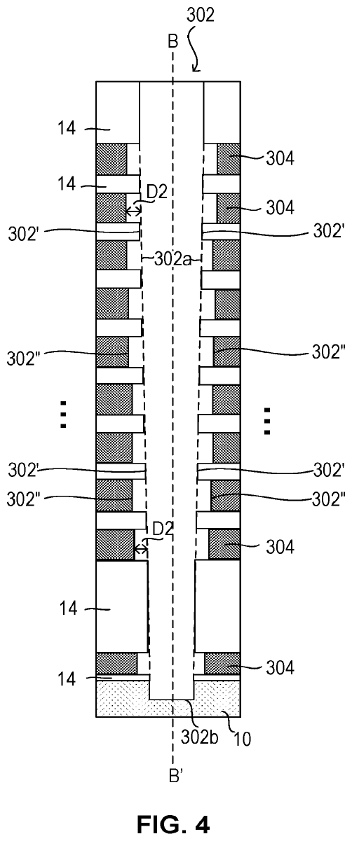

In FIG. 4, an etching process can be applied to remove portions of the sacrificial layers 304 from the initial sidewall 302a. Accordingly, the sacrificial layers 304 can be recessed or offset from the initial sidewall 302a. In some embodiments, the sacrificial layers 304 can be recessed from the initial sidewall 302a by a distance of D2. The distance D2 can be in a range between 10 nm and 20 nm. The etching process can be a wet etch process or a plasma (or dry) etch process. The etching process can selectively etch the sacrificial layers 304, and keep the insulating layers 14 untouched or etched lightly. In an exemplary embodiment of FIG. 4, the sacrificial layers 304 can be SiN, and the etching process can be a wet etch process, where phosphorus acid (e.g., H₃PO₃) can be applied to selectively etch the sacrificial layers 304. When the etching process is completed, the dummy channel hole 302 can have a first sidewall 302′ that is formed along the insulating layers 14 and a second sidewall 302″ that is formed along the sacrificial layers 304.

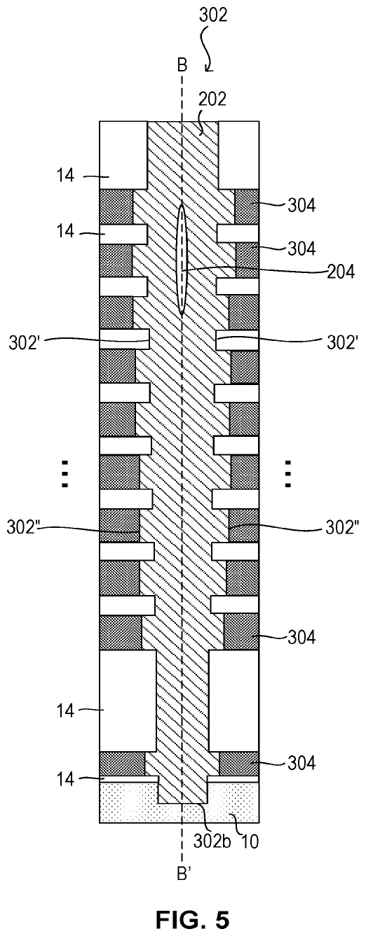

In FIG. 5, a dummy layer 202 can be deposited to fill the dummy channel hole 302. The dummy layer 202 can be formed along the first sidewall 302′ and the second sidewall 302″ of the dummy channel hole 302. Accordingly, the dummy layer 202 can extend through the sacrificial layers 304 and the insulating layers 14, and further be in direct contact with the sacrificial layers 304 and the insulating layers 14. The dummy layer 202 can further extend into the substrate 10 so as to be disposed over the bottom 302b of the dummy channel hole 302. The dummy layer 202 can be made of SiO, SiN, SiCN, polysilicon, or other suitable materials. Any suitable deposition process can be applied to form the dummy layer 202, such as a chemical vapor deposition (CVD) process, a physical vapor deposition (PVD) process, a diffusion process, or an atomic layer deposition process. In some embodiments, one or more gaps (or voids) 204 can be formed in the dummy layer 202. The formation of the gaps 204 can be driven by a number of factors, such as an aspect ratio of the dummy channel hole 302, and/or process conditions of the deposition process.

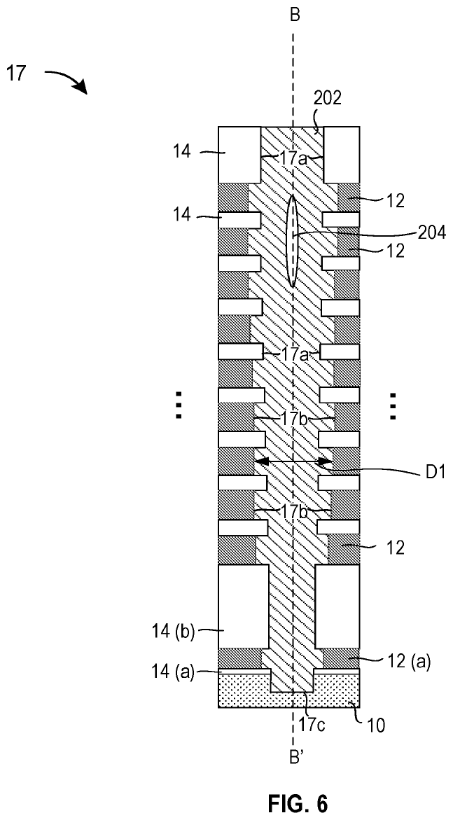

In FIG. 6, the sacrificial layers 304 can be replaced by word line layers 12 so as to form a stack of alternating word line layers 12 and insulating layers 14 over the substrate 10. In order to replace the sacrificial layers 304 with the word line layers 12, a number of slit tranches (not shown) can be formed. The slit trenches can extend along a horizontal direction that is parallel to the substrate 10, such as the X direction. Subsequently, an etching process can be applied to remove the sacrificial layers 304 through the slit structures, where an etching acid or an etching plasma can be introduced through the slit structures. Accordingly, vacancies (or spaces) can be formed between the insulating layers 14 in the initial stack. Further, the word line layers 12 can be formed in the vacancies between the insulating layers 14 in the initial stack to replace the sacrificial layers 304. In some embodiments, the sacrificial layers 304 can be removed and replaced with the word line layers 12 that include a high K layer, glue layers, and/or one or more metal layers. The high K layer can be made of aluminum oxide (Al₂O₃) and/or Hafnium oxide (HfO₂), Tantalum oxide (Ta₂O₅), and/or another material of high K (Dielectric Constant). The metal layer can be made of tungsten (W), or Cobalt (Co), for example.

In some embodiments, before the sacrificial layers 304 are replaced with word line layers 12, a plurality of channel structures (e.g., 18) can be formed in the array region (e.g., 100A) of the initial stack. In some embodiments, when the sacrificial layers are replaced with word line layers, the slit trenches can be filled with conductive materials, such as polysilicon, and/or tungsten to form the slit structures (e.g., 20a and 20b). In addition, word line contacts (e.g., 22) can be formed in the staircase region (e.g., 100B and 100C). The word line contacts can extend from the word line layers 12 in the vertical direction and further extend through the isolation layer (e.g., 24).

When the sacrificial layers 304 are replaced with the word line layers 12, a dummy channel structure 17 can be formed accordingly. As shown in FIG. 6, the dummy channel structure 17 can have similar features to the dummy channel structure 17 in FIG. 2. For example, the dummy channel structure 17 can have a first sidewall 17a along the insulating layers 14, a second sidewall 17b along the word line layers 12, and a bottom 17c positioned in the substrate 10. Each of the word line layers 12 can be located further away from the central axis B-B′ of the dummy channel structure 17 than the insulating layers 14 adjacent to the respective word line layer. In other embodiments, a subset of the word line layers 12 can be located further away from the central axis B-B′ that the insulating layers 14 adjacent to the subset of the word line layer.

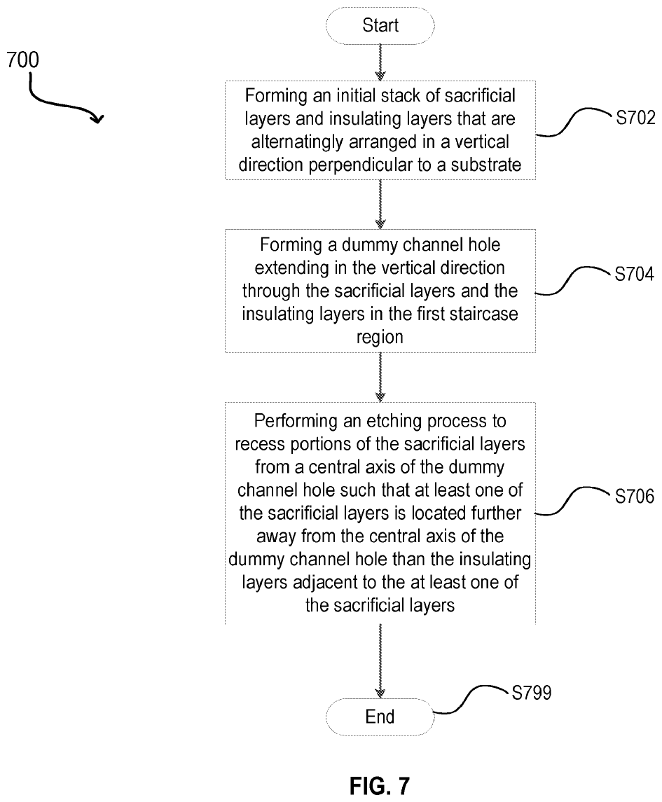

FIG. 7 is a flowchart of a process 700 for manufacturing the disclosed 3D-NAND device in accordance with some embodiments of the present disclosure. The process 700 begins at step S702, where an initial stack of alternating sacrificial layers and insulating layers can be formed over a substrate in a vertical direction perpendicular to a substrate. The initial stack can include a first array region and an adjacent first staircase region in a stair-cased configuration. In some embodiments, the steps S702 can be performed as illustrated with reference to FIG. 1.

At step S704, a dummy channel hole can be formed to extend in the vertical direction through the sacrificial layers and the insulating layers in the first staircase region, and further extend into the substrate. In some embodiments, the steps S704 can be performed as illustrated with reference to FIG. 3.

The process 700 then proceeds to step S706. At step S706, an etching process can be performed to recess or offset portions of the sacrificial layers from a central axis of the dummy channel hole. Accordingly, each of the sacrificial layers is located further away from the central axis of the dummy channel hole than the insulating layers adjacent to the respective sacrificial layer. In other embodiments, a subset of the sacrificial layers can be etched and located further away from the central axis of the dummy channel hole than the insulating layers (e.g., respective adjacent insulating layers). In some embodiments, the step S706 can be performed as illustrated with reference to FIG. 4.

In order to form the dummy channel structure, the process 700 can further include forming a dummy layer in the dummy channel hole, and replacing the sacrificial layers with word line layers, which can be performed as illustrated with reference to FIGS. 5-6.

It should be noted that additional steps can be provided before, during, and after the process 700, and some of the steps described can be replaced, eliminated, or performed in different order for additional embodiments of the process 700. For example, before the sacrificial layers are replaced with word line layers, channel structures can be formed in the array region of the initial stack. In addition, when the sacrificial layers are replaced with word line layers, slit structures and word line contacts can further be formed. Moreover, various additional interconnect structures (e.g., metallization layers having conductive lines and/or vias) may be formed over the first and second contact structures of the 3D-NAND memory device. Such interconnect structures electrically connect the 3D-NAND memory device with other contact structures and/or active devices to form functional circuits. Additional device features such as passivation layers, input/output structures, and the like may also be formed.

The various embodiments described herein offer several advantages over related 3D-NAND memory devices. In the disclosure, dummy channel structures with a thread configuration are provided. The dummy channel structure can include a first sidewall that is formed along the insulating layers and around a central axis, and a second sidewall that is formed along the word line layers and around the central axis, where the second sidewall is located further away from the central axis than the first sidewall. Based on the thread configuration, an effective critical dimension (CD) of the dummy channel structures can be increased. Thus, spacing between the dummy channel structures can be reduced, and collapses in the staircase regions can be prevented.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a stack of word line layers and insulating layers that are alternatingly arranged in a vertical direction perpendicular to a substrate of the semiconductor device, the stack including a first array region and an adjacent first staircase region; and
a dummy channel structure that extends in the vertical direction through the word line layers and the insulating layers in the first staircase region of the stack,
wherein at least one of the word line layers is located further away from a central axis of the dummy channel structure than the insulating layers adjacent to the at least one of the word line layers.

2. The semiconductor device of claim 1, wherein each of the word line layers is located further away from the central axis of the dummy channel structure than the insulating layers adjacent to the respective word line layer.

3. The semiconductor device of claim 1, further comprising:
an isolation layer that is positioned over the substrate, wherein:
the first staircase region is positioned in the isolation layer, and
the dummy channel structure extends through the isolation layer and further extends into the substrate in the vertical direction.

4. The semiconductor device of claim 3, wherein the dummy channel structure includes a dummy layer that is arranged along the word line layers and the insulating layers, and further extends into the substrate.

5. The semiconductor device of claim 1, further comprising:
a second array region,
wherein the first staircase region is arranged between the first array region and the second array region.

6. The semiconductor device of claim 1, further comprising:
a second staircase region,
wherein the first array region is arranged between the first staircase region and the second staircase region.

7. The semiconductor device of claim 4, wherein the dummy layer includes at least one of SiO, SiN, SiCN, SiCON, SiON, or polysilicon.

8. The semiconductor device of claim 1, further comprising:
channel structures formed in the first array region, the channel structures extending through the word line layers and the insulating layers, and further extending into the substrate;
one or more slit structures extending in a horizontal direction parallel to the substrate, and further extending into the substrate, the one or more slit structures extending through the first array region and the first staircase region so as to being arranged among the channel structures; and
word line contacts extending from the word line layers of the first staircase region in the vertical direction.

9. The semiconductor device of claim 1, further comprising:
another dummy channel structure that extends in the vertical direction through the word line layers and the insulating layers in the first array region of the stack.

10. A method for manufacturing a semiconductor device, comprising:
forming an initial stack of sacrificial layers and insulating layers that are alternatingly arranged in a vertical direction perpendicular to a substrate, the initial stack including a first array region and an adjacent first staircase region;
forming a dummy channel hole extending in the vertical direction through the sacrificial layers and the insulating layers in the first staircase region extending into the substrate; and
performing an etching process to recess portions of the sacrificial layers from a central axis of the dummy channel hole such that at least one of the sacrificial layers is located further away from the central axis of the dummy channel hole than the insulating layers adjacent to the at least one of the sacrificial layers.

11. The method of claim 10, wherein each of the sacrificial layers is located further away from the central axis of the dummy channel hole than the insulating layers adjacent to the respective sacrificial layer.

12. The method of claim 10, wherein the forming the dummy channel hole further comprises:
depositing an isolation layer over the substrate such that the first staircase region is arranged in the isolation layer,
wherein the dummy channel hole is formed to extend through the isolation layer, and the sacrificial layers and the insulating layers in the first staircase region.

13. The method of claim 12, further comprising:
depositing a dummy layer in the dummy channel hole to form a dummy channel structure,
wherein the dummy layer is arranged along the sacrificial layers and the insulating layers, and further extends into the substrate.

14. The method of claim 13, further comprising:
forming a channel structure in the first array region of the initial stack, the channel structure extending through the sacrificial layers and the insulating layers, and further extending into the substrate.

15. The method of claim 14, further comprising:
forming a slit structure extending in a horizontal direction parallel to the substrate, and further extending into the substrate, the slit structure extending through the first array region and the first staircase region;
replacing the sacrificial layers with word line layers in the initial stack so as to form a stack of alternating word line layers and insulating layers, the word line layers being formed of a conductive material; and
forming word line contacts extending from the word line layers of the first staircase region in the vertical direction.

16. The method of claim 10, wherein the initial stack further includes a second array region, the first staircase region being arranged between the first array region and the second array region.

17. The method of claim 10, wherein the initial stack further comprises a second staircase region, the first array region being arranged between the first staircase region and the second staircase region.

18. A 3D-NAND memory device, comprising:
a stack of word line layers and insulating layers that are alternatingly arranged in a vertical direction perpendicular to a substrate of the 3D-NAND memory device, the stack including a first array region and an adjacent first staircase region;
a dummy channel structure that extends in the vertical direction through the word line layers and the insulating layers in the first staircase region of the stack, at least one of the word line layers being located further away from a central axis of the dummy channel structure than the insulating layers adjacent to the at least one of the word line layers;
a channel structure formed in the first array region, the channel structure extending through the word line layers and the insulating layers, and further extending into the substrate;
a slit structure extending into the substrate, and further extending in a horizontal direction parallel to the substrate and through the first array region and the first staircase region; and
word line contacts extending from the word line layers of the first staircase region in the vertical direction.

19. The 3D-NAND memory device of claim 18, wherein each of the word line layers is located further away from the central axis of the dummy channel structure than the insulating layers adjacent to the respective word line layer.

20. The 3D-NAND memory device of claim 18, wherein the dummy channel structure includes a dummy layer that is arranged along the word line layers and the insulating layers, and further extends into the substrate.
